(19) United States
(12) Patent Application Publication
(10) Pub. No.: US 2007/0063879 A1
(43) Pub. Date: Mar. 22, 2007

(54) METHOD FOR GENERATING VARIABLE NUMBERS

(75) Inventors: Christophe Moreaux, Simiane (FR); Ahmed Kari, Aix en Provence (FR); David Naura, Aix en Provence (FR); Pierre Rizzo, Aix en Provence (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS SA, Montrouge (FR)

(21) Appl. No.: 11/470,974

(22) Filed: Sep. 7, 2006

(30) Foreign Application Priority Data
Sep. 7, 2005 (FR) 05 09101

(51) Int. Cl. H03M 7/40

(52) U.S. Cl. 341/67

(57) ABSTRACT

A method for generating a variable number includes generating a clock signal, demodulating a received signal of data transmission, supplying a binary signal having variable frequency pulses, and sampling the clock signal by the binary signal to generate bits of a variable number. The method can be applied to RFID tags.

### BACKGROUND OF THE INVENTION

1. Field of the Invention

The present invention relates to the generation of variable numbers in an integrated circuit.

1. Description of the Related Art

The present invention particularly but not exclusively, relates to contactless tags, like RFID tags (Radio-Frequency IDentification tag). These tags usually comprise circuits for sending and receiving modulated radio signals to exchange data with a reader, a power supply circuit for generating from the electromagnetic field generated by the reader a supply voltage of the integrated circuit, a processing unit, and a non-volatile memory, for example of the EEPROM type.

Random or pseudo-random variable numbers are commonly used in the field of cryptography. In addition, some transmission protocols impose the use of variable numbers to determine timeouts. Thus, in the field of contactless tags, a tag must respond to a reader after a certain timeout. The duration of this timeout is randomly determined to limit the risks of collision with the responses sent by other tags that may be in the field sent by the reader.

There are many methods for generating a variable number. Thus, some methods use a noise signal which is sampled to generate a random variable. In the patent application EP 1 143 616, a jagged signal is sampled by a clock signal which frequency is different from the frequency of the jagged signal. The voltage of each sample is compared to a threshold voltage, and the result of the comparison supplies the value of a bit of the pseudo-random number generated.

These methods require the implementation of various components, particularly two decorrelated oscillators, which have a non negligible electrical consumption. Now, in a RFID tag powered by the electromagnetic field emitted by a reader, it is crucial that the electrical consumption of the tag is as low as possible.

### BRIEF SUMMARY OF THE INVENTION

One embodiment of the present invention generates variable numbers using a limited number of components having low electrical consumption.

According to an embodiment of the invention, a method comprises steps of-demodulating a received signal of data transmission to supply a binary signal comprising variable frequency pulses, and sampling a clock pulse by the binary signal, to supply samples constituting the bits of a variable number.

According to one embodiment of the invention, the clock signal has a frequency comprised in a first frequency band, and the frequency of the binary signal pulses is comprised in a second frequency band larger than the first frequency band.

According to one embodiment of the invention, the clock signal has a frequency larger than the frequency of the binary signal pulses.

According to one embodiment of the invention, the clock signal has a frequency more than ten times larger than the frequency of the binary signal pulses.

According to one embodiment of the invention, each pulse of the binary signal is subjected to a variable delay.

Preferably, the delay applied to each pulse of the binary signal is determined according to the variable number generated.

According to one embodiment of the invention, the delay applied to each pulse of the binary signal is generated in order to be sensitive to noise.

According to an embodiment of the invention, a device for generating a variable number includes a generator of a clock signal, a demodulation circuit demodulating a received signal of data transmission and supplying a binary signal having variable frequency pulses, and a sampling circuit sampling the clock signal by the binary signal, and supplying samples constituting the bits of the variable number generated.

According to one embodiment of the invention, the clock signal has a frequency comprised in a first frequency band, and the frequency of the binary signal pulses is comprised in a second frequency band larger than the first frequency band.

According to one embodiment of the invention, the clock signal has a frequency larger than the frequency of the binary signal pulses.

According to one embodiment of the invention, the clock signal has a frequency more than ten times larger than the frequency of the binary signal pulses.

According to one embodiment of the invention, the sampling circuit comprises a shift register including an input of clock signal receiving the binary signal, a data input receiving the clock signal, and a parallel output of variable number.

According to one embodiment of the invention, the device for generating variable numbers comprises a delay circuit subjecting to a variable delay each pulse of the binary signal at the input of the sampling circuit.

Preferably, the delay applied to each pulse of the binary signal by the delay circuit is adjustable according to the variable number generated.

Advantageously, the delay circuit is made in order to be sensitive to noise.

According to an embodiment of the invention, an integrated circuit includes a device for generating a variable number as described above for determining a delay of response to a message received.

According to one embodiment of the invention, the integrated circuit comprises circuits for sending and receiving modulated radio signals, and a processing unit. According to one embodiment of the invention, the integrated circuit comprises a demodulation circuit supplying a binary signal used for generating the variable number, the variable number being accessible to a processing unit.

According to an embodiment of the invention, an integrated circuit includes a means for receiving wireless data transmission, a means for generating a binary signal based upon the received wireless data transmission, a local oscillator configured to generate a clock signal having a second frequency, a random number generator device configured to generate a variable number based upon the clock signal and the the binary signal, and a means for determining a delay of response to the received wirelesss data transmission based upon the the variable number.

### BRIEF DESCRIPTION OF THE SEVERAL VIEWS OF THE DRAWING(S)

These and other advantages and features of the present invention will be presented in greater detail in the following description of an embodiment of the invention, given in relation with, but not limited to the following figures:

FIG. 1 shows in block form a first embodiment of a device for generating variable numbers according to the invention;

FIG. 2 is an electronic diagram of an exemplary shift register used in the device shown in FIG. 1;

FIG. 3 shows in the form of timing charts the operation of the device shown in FIG. 1;

FIG. 4 shows in block form a second embodiment of a device for generating variable numbers according to the invention;

FIG. 5 shows in the form of timing charts the operation of the device shown in FIG. 4;

FIG. 6 is an electronic diagram of an exemplary delay circuit with adjustable delay used in the device shown in FIG. 4; and

FIG. 7 shows in block form the architecture of a contactless tag integrating a device according to the invention.

### DETAILED DESCRIPTION OF THE INVENTION

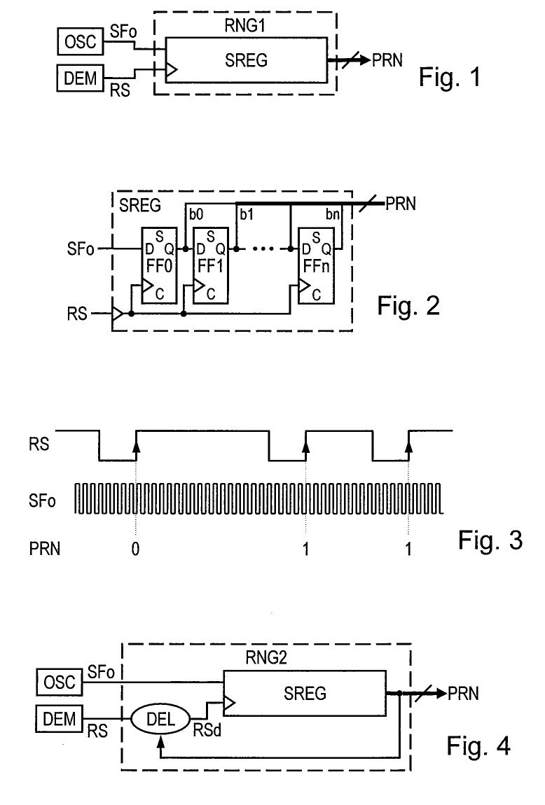

FIG. 1 shows a random number generator (RNG) device 10a for generating variable numbers according to an embodiment of the invention. The device 10a comprises a shift register SREG 12 comprising an input of clock signal 14 (also referred to as a binary signal input) and an input of signal to be sampled 16 (also referred to as a data input). The input of clock signal 14 is connected to the output of a demodulator DEM 18 supplying a demodulated binary signal RS. The input of signal to be sampled 16 is connected to the output of an oscillator OSC 20 supplying a clock signal SFo.

As shown in FIG. 2, the shift register SREG 12 comprises one or more cells 22, for example 16 cells, for memorizing as many bits of the variable word generated. Each cell 22 of the shift register 12 is connected to a parallel output 24 of the RNG device 10a delivering in parallel all the bits of a variable number PRN generated.

The shift register SREG 12 can be made in a standard way, where the cells 22 of the register 12 are flip flops FF0-FFn. The flip-flops are mounted in series (output Q connected to input D of the following flip-flop). In addition, an input of clock signal 26 of each flip-flop is connected to the input of the clock signal 14 of the register SREG 12. Output Q of each flip-flop is further connected to the parallel output 24 of the shift register 12. Each flip-flop therefore memorizes a bit b0-bn of the variable number generated which is accessible on the parallel output 24 of the shift register 12. The register SREG 12 therefore comprises a number of flip-flops corresponding to a size of the variable number to be generated.

FIG. 3 shows the shape of the input signals RS and SFo applied to the inputs 14 and 16, respectively, of the shift register SREG 12. The signal RS is a (two-state) binary signal and has rising edges which frequency is variable. The signal SFo is a clock signal, that is a binary signal which frequency is substantially constant. As this signal is locally generated, its frequency can vary, particularly according to the temperature to which the oscillator is subjected, and according to the supply voltage of the oscillator. In the case of a contactless tag which is powered from the electromagnetic field applied to the tag by a reader, the supply voltage of the tag depends on the proximity of the tag with the reader and of the orientation of the tag in the field. The supply voltage of this tag is therefore very variable.

At each rising edge of the signal RS, a sample of the clock signal, constituting a random variable equal to 0 or 1, is taken and charged into the shift register SREG. The period of the clock signal is about 0.5 μs, whereas the time between two successive rising edges of the signal RS ranges from about 6.25 μs to 50 μs. Consequently, the duration between two successive rising edges of the signal RS, and the sampling period is about 12.5 to 100 times longer than the period of the clock signal. The variable number generated is therefore very sensitive to a small variation of the frequency of the clock signal SFo or of the difference between two successive rising edges of the binary signal RS.

The binary signal RS comes from the demodulator DEM 18 which demodulates a signal transmitted under the form of a modulated carrier signal. It is thus sure that the clock signal produced by the local oscillator OSC 20 of a chip (not shown) is decorrelated from the received and demodulated RS signal. The random nature of the numbers PRN obtained at the output 24 of the register SREG 12 is therefore ensured.

If each variable number to be generated must comprise a certain number of bits, it can only be obtained after receiving as many rising edges in the signal received. The method according to the invention in one embodiment is therefore applicable if a variable number is not needed before receiving the number of rising edges necessary for generating the variable number.

FIG. 4 shows a second embodiment of the RNG device 10b for generating variable numbers according to the invention. The elements identical to those of FIG. 1 are indicated by the same references. The RNG device 10b for generating random numbers shown in this figure comprises the shift register SREG 12 and a delay circuit DEL 28 with adjustable delay interposed between the output of the demodulator DEM 18 and the clock input 14 of the shift register SREG 12. The delay circuit DEL 28 is advantageously controlled by the output 24 of the register SREG 12 for applying to each rising edge of the signal RS a variable delay to generate an output signal RSd.

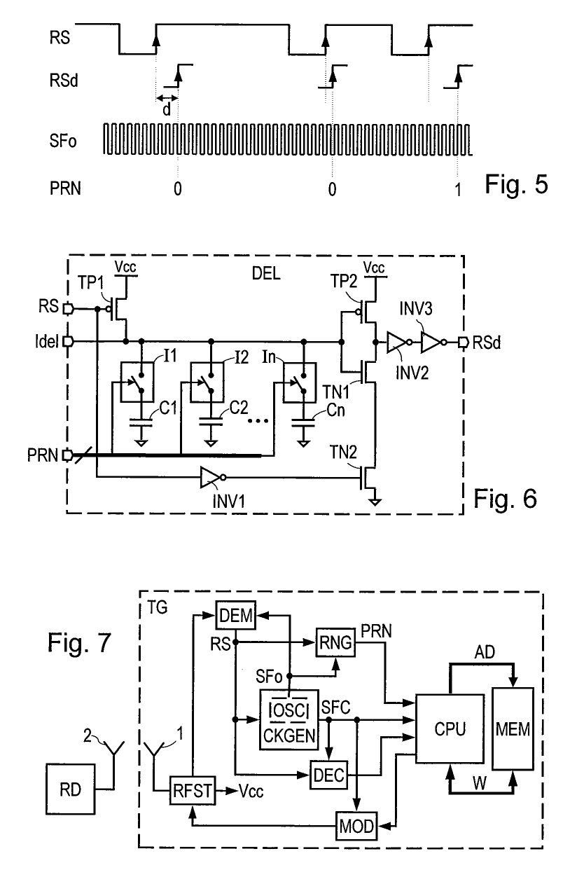

FIG. 5 shows the operation of the device shown in FIG. 4. More particularly, FIG. 5 shows the shapes of the signal RS, of the output signal RSd of the delay circuit DEL 28, and of the clock signal SFo. The signal RSd comprises for each rising edge of the signal RS a delayed rising edge which duration d is variable from one edge to the other. The signal SFo is sampled at each rising edge of the delayed signal RSd to successively supply the value of each bit of the variable number PRN, these bits being stored in the shift register SREG 12.

FIG. 6 shows an example of delay circuit 28 with variable delay DEL. This circuit 28 comprises an input stage 29 including an input PMOS transistor TP1 having a gate terminal 30 connected to an input 32 of the circuit DEL 28 receiving the demodulated signal RS and a drain terminal 34 receiving a supply voltage Vcc. A source terminal 36 of the transistor TP1 is connected to an input 38 connected to a constant current source Idel. The circuit DEL 28 further comprises several capacitive stages 39, each comprising a capacitor C1-Cn mounted in series with a switch I1-In, which other terminal is connected to the current source Idel and to the source terminal 36 of the transistor TP1. The switches I1-In receive on a control input the value of a bit of the variable word PRN at the output 24 of the shift register SREG 12. The number of capacitive stages 39 matches the number of bits of the variable word applied to the control inputs of the switches. Thus, if the number of bits of the variable numbers generated is equal to 16, the number of capacitive stages 39 ranges from 1 to 16. In one embodiment, only one part of the bits of the variable word, for example the most significant bits or the least significant bits, can be used for switching the capacitor C1-Cn.

The delay circuit DEL 28 further comprises an output stage 40 comprising three transistors TP2, TN1 and TN2 mounted in series, as well as two inverters INV2, INV3 mounted in series. A source terminal 42 of the transistor TP2 receives the supply voltage Vcc and a drain terminal 44 of this transistor is connected to a drain terminal 46 of the transistor TN1, as well as to an input 48 of the inverter INV2. Gate terminals 50 of the transistors TP2 and TN1 are connected to the drain terminal 36 of the transistor TP1. A source terminal 52 of the transistor TN1 is connected to a drain terminal 54 of the transistor TN2 which source terminal 56 is put to the ground and which gate terminal 58 is linked to the input 32 of the demodulated signal RS through an inverter INV1. The delayed demodulated signal RSd is obtained at an output 60 of the inverter INV3.

When the input signal RS is at 0, the transistor TP1 is ON. The result is the charge of the capacitors C1-Cn of the capacitive stages corresponding to a bit at 1 of the variable number PRN. During this time, the control voltage applied to the gate terminals of the transistors TP2, TN1 and TN2 is at 1. As a result, the transistors TN1 and TN2 are ON, while the transistor TP2 is OFF. Consequently, the input of the inverter INV2 is at 0, and therefore the output signal RSd is also at 0.

When the input signal RS goes to 1 (arrival of a rising edge), the input transistor TP1 and the transistor TN2 block, which triggers the discharge at constant current of the capacitors C1-Cn by the current source Idel. The voltage applied to the gate terminals of the transistors TP2 and TN1 decreases until going below the threshold voltage of the transistors TP2 and TN1. As a result, the transistor TP2 unblocks and the transistor TN i blocks. The output voltage RSd then goes to 1.

A rising edge of the signal RS applied at the input 32 of the delay circuit DEL 28 is therefore delayed by a delay corresponding to the discharge time of the connected capacitors C1-Cn. The discharge time depends on the number of capacitors to be discharged, i.e., connected and previously charged.

The delay circuit DEL 28 is advantageously made to be sensitive to noise.

The invention as described before more particularly applies to an integrated circuit 62 of the contactless tag type as shown in FIG. 7. The integrated circuit 62 (also referred to as a TG integrated circuit) comprises a processing unit CPU 64 coupled to a memory MEM 66. The processing unit 64 communicates with an external reader RD 68 coupled to an antenna 2, thanks to an antenna 1 connected to a radio stage RFST 70. The stage RFST 70 is connected to a demodulator DEM 72 and to a modulator MOD 74. The demodulator 72 is connected to a decoder DEC 76 which supplies to the processing unit CPU 64 received and demodulated data. The modulator 74 modulates data supplied by the processing unit 64 and applies the modulated data to the stage RFST 70 in view of sending them to the reader RD 68. The processing unit CPU 64 is connected to the memory MEM 66 by address and data buses, used to transmit an address AD to be accessed and a word W to be stored or read in the memory 66 at the address AD.

In addition, the stage RFST 70 produces from an electric or electromagnetic field radiated by the reader RD 68, a continuous voltage Vcc for supplying the TG integrated circuit 62. The integrated circuit 62 also comprises a circuit for generating a clock signal CKGEN comprising a local oscillator OSC 78 generating a first clock signal SFo from which a second clock signal SFC is generated. The second clock signal SFC is used to clock the modulator MOD 74, whereas the first clock signal SFo clocks the demodulator DEM 72.

The data transmission between the TG integrated circuit 62 and the reader RD 68 is for example performed using an ASK modulation (Amplitude Shift Keying) or a PSK modulation (Phase Shift Keying). The demodulator DEM 72 supplies to the decoder 76 a signal RS which shape matches the envelope of the signal received. The decoder 76 samples this signal with the clock signal SFC to obtain a binary signal containing the data received.

The integrated circuit 62 further comprises an RNG device 10 (such as RNG device 10a or RNG device 10b) for generating variable numbers according to embodiments of the invention, connected to the output of the oscillator OSC 78 and to the output of the demodulator DEM 72 to receive the signals SFo and RS. The variable numbers PRN produced by the RNG device 10 are accessible to the processing unit CPU 64, in particular for determining a delay of response to a message received.

It will be clear to those skilled in the art that the device according to the invention is susceptible of several variations. Thus, the invention is not limited to sampling a clock signal by a signal having a frequency inferior to the frequency of the clock signal. Indeed, variable numbers can be obtained even if this condition is not satisfied.

The sampling of the clock signal can alternately be performed on the falling edges of the demodulated signal, or even on all the edges of this signal.

In addition, the use of a shift register is not necessary, unless all the bits of each variable word generated must be supplied in parallel. Indeed, a simple flip-flop D allows the clock signal to be sampled and successively supplies random variables, each constituting a bit of the variable word.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

1. A method for generating a variable number comprising:
generating a clock signal;
demodulating a received signal of data transmission, to supply a binary signal comprising variable frequency pulses; and
sampling the clock signal by the binary signal, to supply samples constituting bits of the variable number.

2. The method according to claim 1, wherein the clock signal has a frequency comprised in a first frequency band, and a frequency of the binary signal pulses is comprised in a second frequency band larger than the first frequency band.

3. The method according to claim 1, wherein the clock signal has a frequency larger than a frequency of the binary signal pulses.

4. The method according to claim 1, wherein the clock signal has a frequency more than ten times larger than a frequency of the binary signal pulses.

5. The method according to claim 1, wherein each pulse of the binary signal is subjected to a variable delay.

6. The method according to claim 5, wherein the delay applied to each pulse of the binary signal is determined according to the variable number generated.

7. The method according to claim 5, wherein the delay applied to each pulse of the binary signal is generated in order to be sensitive to noise.

8. A device for generating a variable number comprising:
a generator of a clock signal;
a demodulation circuit configured to demodulate a received signal of data transmission and supply a binary signal comprising variable frequency pulses; and
a sampling circuit configured to sample the clock signal by the binary signal, and supply samples constituting bits of the variable number generated.

9. The device according to claim 8, wherein the clock signal has a frequency comprised in a first frequency band, and a frequency of the binary signal pulses is comprised in a second frequency band larger than the first frequency band.

10. The device according to claim 8, wherein the clock signal has a frequency larger than a frequency of the binary signal pulses.

11. The device according to claim 8, wherein the clock signal has a frequency more than ten times larger than a frequency of the binary signal pulses.

12. The device according to claim 8, wherein the sampling circuit comprises a shift register including
an input of clock signal configured to receive the binary signal,
a data input configured to receive the clock signal, and
a parallel output of variable number.

13. The device according to claim 12, further comprising a delay circuit configured to subject to a variable delay each pulse of the binary signal at the input of clock signal of the sampling circuit.

14. The device according to claim 13, wherein the delay applied to each pulse of the binary signal by the delay circuit is adjustable according to the variable number generated.

15. The device according to claim 13, wherein the delay circuit is made in order to be sensitive to noise.

16. An Integrated circuit for generating a variable number and determining a delay of response to a message received, comprising:
a generator of a clock signal;
a demodulation circuit configured to demodulate a received signal of data transmission and supply a binary signal comprising variable frequency pulses; and
a sampling circuit configured to sample the clock signal by the binary signal and supply samples constituting bits of the variable number generated.

17. The integrated circuit according to claim 16, further comprising circuits for sending and receiving modulated radio signals, and a processing unit.

18. The integrated circuit according to claim 17, wherein the variable number is accessible to the processing unit.

19. An integrated circuit comprising:
means for receiving a wireless data transmission;
means for generating a binary signal based upon the received wireless data transmission, the binary signal having a plurality of pulses and a first frequency;
a local oscillator configured to generate a clock signal having a second frequency;
a random number generator device configured to generate a variable number based upon the clock signal and the the binary signal, the variable number having a plurality of bits; and
means for determining a delay of response to the received wirelesss data transmission based upon the the variable number.

20. The integrated circuit according to claim 19, wherein the means for receiving comprises
an antenna; and
a radio stage coupled to the antenna.

21. The integrated circuit according to claim 19, wherein the means for generating the binary signal is a demodulation circuit configured to demodulate the received wireless data transmission.

22. The integrated circuit according to claim 19, wherein the means for determining the delay of response based upon the variable number is a CPU configured to receive the variable number.

23. The integrated circuit according to claim 19, wherein the random number generator device samples the clock signal at the first frequency of the binary signal to generate bit values for the pluarity of bits of the variable number.

24. The integrated circuit according to claim 23, wherein the first frequency is a variable frequency.

25. The integrated circuit according to claim 19, wherein the first frequency is larger than the second frequency.

26. The integrated circuit according to claim 19, wherein the random number generator device comprises a shift register, the shift register including
a binary signal input configured to receive the binary signal pulses,
a data input configured to receive the clock signal, and
a parallel output configured to receive the variable number.

27. The integrated circuit according to claim 26, wherein the random number generator further comprises a delay circuit configured to apply a variable delay to each pulse of the binary signal at the binary signal input.

28. The integrated circuit according to claim 27, wherein the variable delay applied to each pulse of the binary signal by the delay circuit is based upon the variable number generated.
